(19) United States
(12) Patent Application Publication
(10) Pub. No.: US 2007/0138573 A1
(43) Pub. Date: Jun. 21, 2007

(54) SEMICONDUCTOR DEVICE AND MANUFACTURING METHOD OF THE SAME

(75) Inventors: Keiichiro KASHIHARA, Tokyo (JP); Tomonori Okudaira, Tokyo (JP); Tadashi Yamaguchi, Tokyo (JP); Atsushi Ishinaga, Hyogo (JP); Kenshi Kanegae, Osaka (JP); Akihiko Tsuzumitani, Kyoto (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Renesas Technology Corp., Chiyoda-ku (JP); Matsushita Electric Industrial Co., Ltd., Kadoma-shi (JP)

(21) Appl. No.: 11/565,913

(22) Filed: Dec. 1, 2006

(30) Foreign Application Priority Data
Dec. 2, 2005 (JP) JP2005-348743

(51) Int. Cl. H01L 29/76; H01L 21/336

(52) U.S. Cl. 257/382; 438/300; 257/413; 257/E29.156

(57) ABSTRACT

A semiconductor device according to the present invention comprises a silicon substrate, a gate electrode formed on a main surface of the silicon substrate with a gate insulation film therethrough, a sidewall spacer formed so as to cover a side surface of the gate electrode and including at least two layers of a silicon oxide film as a lowermost layer and a silicon nitride film formed thereon, a source region and a drain region formed in the main surface of the silicon substrate so as to sandwich the gate electrode, a protection film formed so as to cover an end surface of the silicon oxide film without extending below said silicon nitride film, the end surface being on a side of said source region and said drain region, and a metal silicide layer formed in the source region and the drain region on a side of said protection film away from said gate electrode.

### BACKGROUND OF THE INVENTION

1. Field of the Invention

The present invention relates to a semiconductor device and a manufacturing method of the same, and more particularly, to a semiconductor device using silicide process and a manufacturing method of the same.

2. Description of the Background Art

First, according to a transistor structure of an MIS (Metal-Insulator Semiconductor) on a semiconductor substrate, as shown in Japanese Patent Application Laid-Open No. 2004-071959, a first sidewall insulation film is provided so as to cover the side surface of a gate electrode provided on a main surface of the silicon substrate. Thus, the first sidewall insulation film comprises two layers such as a lower oxide sidewall film and a nitride sidewall film. Furthermore, according to the MIS transistor structure shown in Japanese Patent Application Laid-Open No. 2004-071959, a second sidewall insulation film is provided so as to cover the surface of the first sidewall insulation film. Thus, according to the MIS transistor structure shown in Japanese Patent Application Laid-Open No. 2004-071959, a cobalt silicide layer is provided outside the second sidewall insulation film with respect to the gate electrode and at the upper position of source and drain regions. In addition, the second sidewall insulation film buries a removed part formed at the lower part of the oxide sidewall film.

According to the background art, after the first sidewall insulation film has been formed, a surface cleaning is performed with a HF solution in order to remove a silicon natural oxide film. However, the oxide sidewall film positioned at the lowermost layer of the first sidewall insulation film is also etched away by the HF solution. Therefore, the side surface of the oxide sidewall film of the first sidewall insulation film after cleaned is retreated from the side surface of the nitride sidewall film toward the gate electrode. That is, a removed part is formed at the lower end of the oxide sidewall film.

When the oxide sidewall film is retreated, a cobalt film is formed at that retreated part. Therefore, when the cobalt silicide layer is formed from the cobalt film by a heat treatment, the cobalt silicide layer extends from the end of the first sidewall insulation film to the gate electrode and grows.

Therefore, unexpected junction leak current is increased due to the extending cobalt silicide layer at the end of the first sidewall insulation film, which lowers the driving ability of a transistor and increases power consumption.

### SUMMARY OF THE INVENTION

It is an object of the present invention to provide a semiconductor device in which a junction leak current is not increased at the end of a first sidewall insulation film, as well as a manufacturing method of such a semiconductor device.

A semiconductor device according to the present invention comprises a semiconductor substrate, a gate electrode, a sidewall spacer, a source region and a drain region, a protection film, and a metal silicide layer. The gate electrode is formed on a main surface of the semiconductor substrate with a gate insulation film therethrough. The sidewall spacer is formed so as to cover a side surface of the gate electrode and including at least two layers of a silicon oxide film as a lowermost layer and a silicon nitride film formed thereon. The source region and the drain region are formed in the main surface of the semiconductor substrate so as to sandwich the gate electrode. The protection film is formed so as to cover an end surface of the silicon oxide film without extending below the silicon nitride film, the end surface being on a side of the source region and the drain region. The metal silicide layer is formed in the source region and the drain region on a side of the protection film away from the gate electrode.

Since the semiconductor device according to the present invention comprises the protection film that covers the end surface of the silicon oxide film, the metal silicide film is prevented from entering in the direction of the gate electrode, so that unnecessary junction leak current is prevented from being increased.

A manufacturing method of a semiconductor device according to the present invention comprises a step of forming a gate electrode on a main surface of the semiconductor substrate with a gate insulation film therethrough; a step of forming a source region and a drain region in the main surface of the semiconductor substrate so as to sandwich the gate electrode; and a step of forming a sidewall spacer that covers a side surface of the gate electrode and includes at least two layers of a silicon oxide film as a lowermost layer and a silicon nitride film formed thereon. The manufacturing method of the semiconductor device according to the present invention further comprises a step of forming a protection film formed so as to cover at least an end surface of the silicon oxide film on a side of the source region and the drain region by forming an insulation film and etching back the insulation film after the sidewall spacer has been formed; and a step of forming a metal silicide layer in the source region and the drain region on a side of the sidewall spacer away from the gate electrode.

Since the manufacturing method of the semiconductor device according to the present invention comprises the step of forming the protection film that covers the end surface of the silicon oxide film, the metal silicide film is prevented from entering in the direction of the gate electrode, so that unnecessary junction leak current is prevented from being increased.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a semiconductor device according to an embodiment 1 of the present invention;

FIG. 2 is a sectional view showing a step of forming a protection film of the semiconductor device according to the embodiment 1 of the present invention;

FIG. 3 is a sectional view after the protection film has been formed in the semiconductor device according to the embodiment 1 of the present invention;

FIGS. 4A to 4F are views to explain the protection film;

FIG. 5 is a sectional view to explain nitridation of a silicon oxide film of a semiconductor device according to an embodiment 2 of the present invention;

FIG. 6 is a sectional view showing a semiconductor device according to an embodiment 4 of the present invention;

FIG. 7 is a sectional view to explain a manufacturing step of a conventional semiconductor device;

FIG. 8 is a sectional view to explain a manufacturing step of the conventional semiconductor device;

FIG. 9 is a sectional view to explain a manufacturing step of the conventional semiconductor device;

FIG. 10 is a sectional view to explain a manufacturing step of the conventional semiconductor device;

FIG. 11 is a sectional view to explain a manufacturing step of the conventional semiconductor device;

FIG. 12 is a sectional view to explain a manufacturing step of the conventional semiconductor device; and

FIG. 13 is a sectional view to explain a problem in the conventional semiconductor device.

### DESCRIPTION OF THE PREFERRED EMBODIMENTS

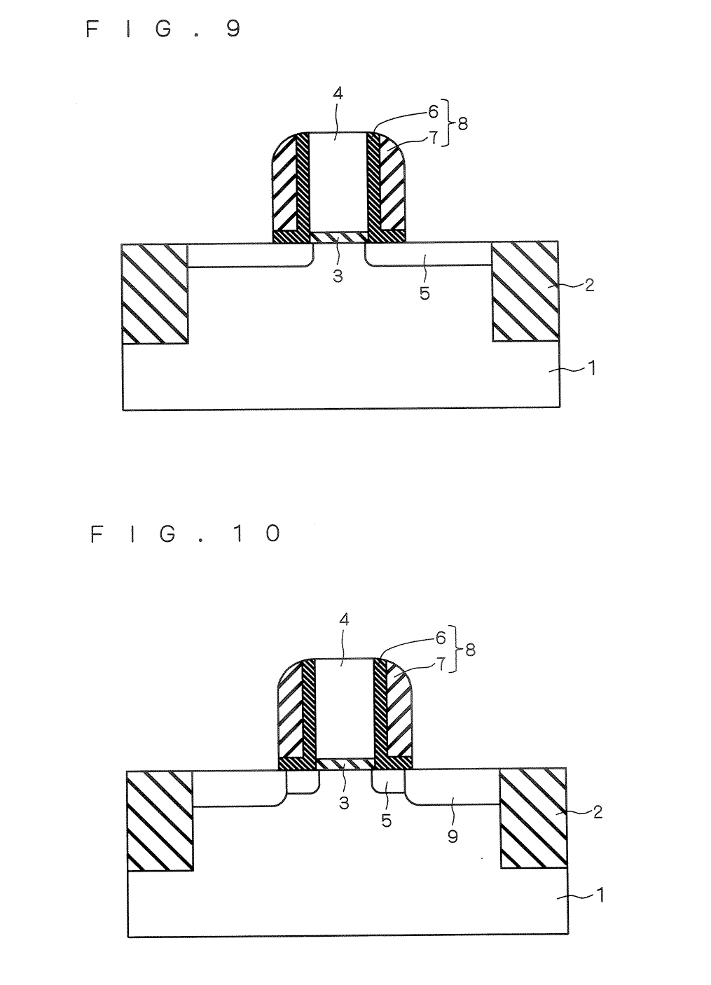

First, a method of forming an MIS transistor structure on a semiconductor substrate that is an assumption of the present invention. An element isolation 2 is formed in a silicon substrate 1 by a well-known method as shown in FIG. 7. A gate insulation film 3 is formed on a region of the silicon substrate 1 sandwiched between the element isolations 2 by thermal oxidation or CVD (Chemical Vapor Deposition) or the like. For example, as a gate insulation film 3, a silicon oxide film having a thickness of 2 nm is employed. Further in FIG. 7, a polysilicon or amorphous silicon is formed on the gate insulation film 3 by CVD and a gate electrode 4 is formed by combining lithography and etching.

Then, as shown in FIG. 8, a first impurity diffusion layer 5 is formed in the silicon substrate 1 so as to sandwich the gate electrode 4. The first impurity diffusion layer 5 is formed by ion implantation using the gate electrode 4 as a mask. When a semiconductor device shown in FIG. 8 is a PMOS, P-type impurity, for example B (boron), is implanted at a concentration of 1E13 to 1E14/cm² to form the first shallow impurity diffusion layer 5 at a low concentration. Meanwhile, when the semiconductor device shown in FIG. 8 is a NMOS, N-type impurity, for example As (arsenic) or P (phosphorous), is implanted at a concentration of 1E13 to 1E14/cm² to form the first shallow impurity diffusion layer 5 at a low concentration.

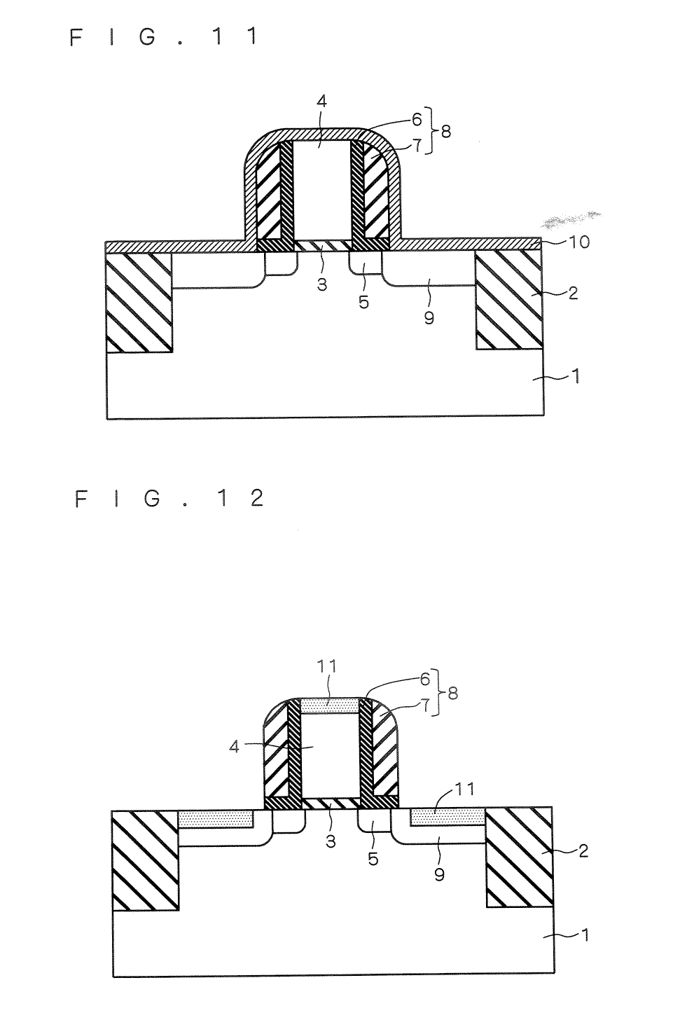

Then, two layers such as a silicon oxide film 6 and a silicon nitride film 7 are formed on the silicon substrate 1. In addition, the silicon oxide film 6 is formed under the silicon nitride film 7. A sidewall spacer 8 is formed so as to cover the gate insulation film 3 and the side surface of the gate electrode 4 by etching back the silicon oxide film 6 and the silicon nitride film 7. As shown in FIG. 9, the sidewall spacer 8 is provided such that the silicon nitride film 7 is laminated on the silicon oxide film 6. In addition, although the sidewall spacer 8 has a two-layer structure in FIG. 9, it may have a multilayer structure comprising three layers or more and having a silicon oxide film as a lowermost layer.

Then, as shown in FIG. 10, a second impurity diffusion layer 9 is formed on the silicon substrate 1 so as to sandwich the gate electrode 4. The second impurity diffusion layer 9 is formed by ion implantation using the gate electrode 4 as a mask. When the semiconductor device shown in FIG. 10 is a PMOS, P-type impurity, for example B (boron), is implanted at a concentration of 1E15 to 1E16/cm² to form the second deep impurity diffusion layer 9 at a concentration higher than that of the first impurity diffusion layer 5. Meanwhile, when the semiconductor device shown in FIG. 10 is a NMOS, N-type impurity, for example As (arsenic) or P (phosphorous), is implanted at a concentration of 1E15 to 1E16/cm² to form the second deep impurity diffusion layer 9 at a concentration higher than that of the first impurity diffusion layer 5.

Then, in order to activate the first impurity diffusion layer 5 and the second impurity diffusion layer 9, a heat treatment such as a lamp annealing is performed. Then, a silicon natural oxide film formed on the surface of the first impurity diffusion layer 5 and the second impurity diffusion layer 9 and the like is removed. A method of removing the silicon natural oxide film includes a surface cleaning method using a HF solution.

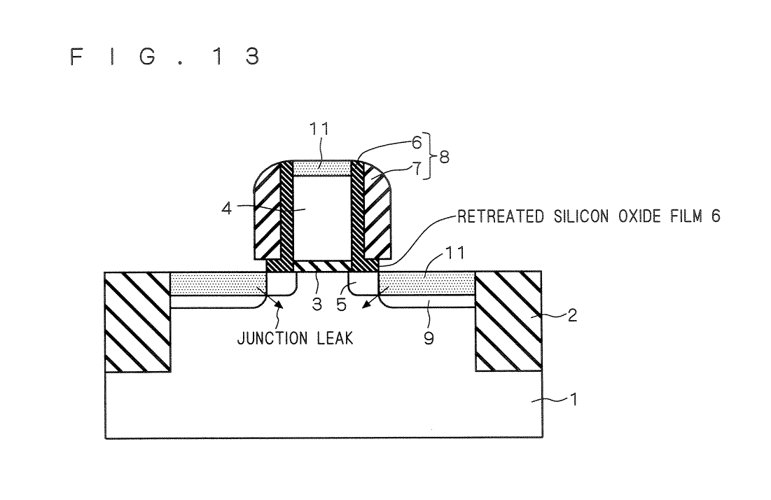

Then, a metal film 10 such as Co or Ni is formed on the gate electrode 4, the first impurity diffusion layer 5 and the second impurity diffusion layer 9 as shown in FIG. 11. In addition, the thickness of the metal film 10 is 5 to 15 nm, for example. Then, a heat treatment at 300° C. to 500° C. to react the underlaying silicon of the gate electrode 4, the first impurity diffusion layer 5 and the second impurity diffusion layer 9 with the metal film 10 to form a metal silicide film 11. When Co is used as the metal film 10, the formed silicide film 11 comprises Co₂Si and CoSi and when Ni is used as the metal film 10, the formed metal silicide film 11 comprises Ni₂Si and NiSi.

Then, unreacted metal film 10 is removed with acid (mixture of sulfuric acid and hydrogen peroxide solution). Thus, an MIS transistor having the metal silicide film 11 is formed as shown in FIG. 12. Then, the stable and low-resistance metal silicide film 11 can be formed by performing a second heat treatment. In addition, when Co is used as the metal film 10, the temperature of the second heat treatment is set to 550° C. to 800° C., for example to form the metal silicide film 11 comprising CoSi, and when Ni is used as the metal film 10, the temperature of the second heat treatment is set to 400° C. to 600° C., for example to form the metal silicide film 11 comprising NiSi.

However, as describe above, since the surface cleaning is performed with the HF solution to remove the silicon natural oxide film after the sidewall spacer 8 has been formed, the silicon oxide film 6 positioned at the lowermost part of the sidewall spacer 8 is etched away by the HF solution. Therefore, the side surface of the silicon oxide film 6 is retreated from the side surface of the silicon nitride film 7 in the sidewall spacer 8 toward the gate electrode 4 after the cleaning as shown in FIG. 13.

When the metal film 10 is formed as shown in FIG. 11, if the silicon oxide film 6 is retreated as described above, the metal film 10 is formed at the retreated part. Therefore, when the silicide film 11 is formed from the metal film 10 by the heat treatment, the metal silicide film 11 extends from the end of the sidewall spacer 8 toward the gate electrode 4 (toward the region of the first impurity diffusion layer 5) and grows.

Therefore, an unexpected leak junction current is increased at the end of the sidewall spacer 8 due to the metal silicide film 11 at that part, which lowers the driving ability of the transistor and increases power consumption.

Thus, according to the following embodiments, a description will be made of a semiconductor device in which a junction leak current is not increased at the end of a sidewall spacer 8 and its manufacturing method.

### Embodiment 1

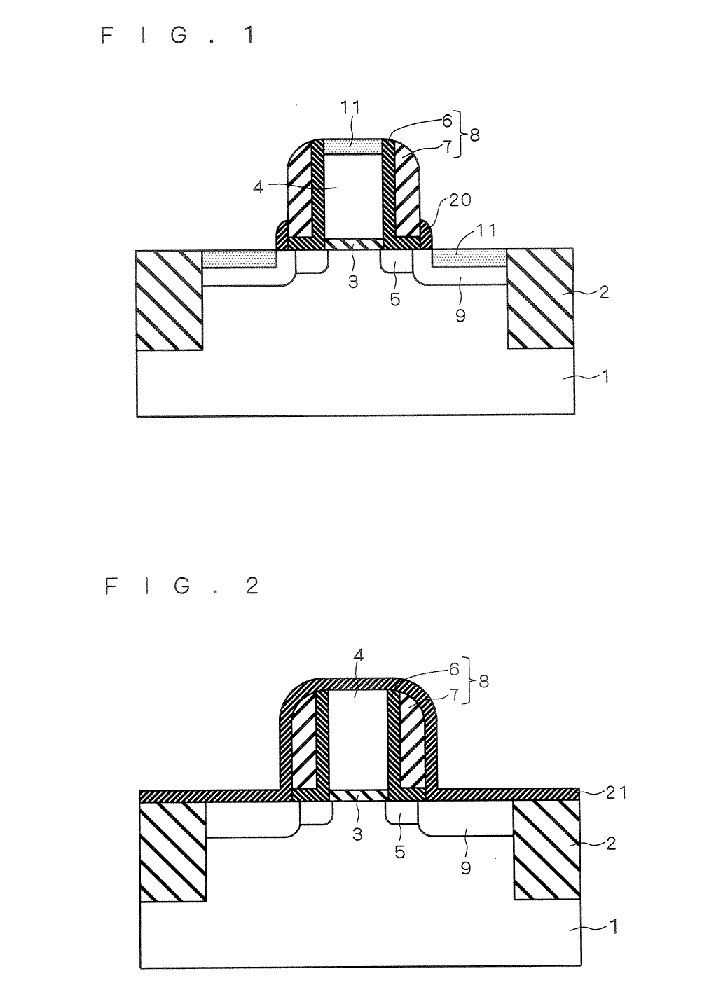

FIG. 1 is a sectional view showing a semiconductor device according to this embodiment. According to the semiconductor device shown in FIG. 1, an MIS transistor (referred to as the transistor simply hereinafter) is formed on a silicon substrate 1 isolated by element isolations 2. According to this embodiment, a device after 65 nm node generation is assumed. According to the transistor shown in FIG. 1, a sidewall spacer 8 is formed on the side surface of a gate insulation film 3 and a gate electrode 4, and first and second impurity diffusion layers 5 and 9 that become a source region and a drain region, respectively are formed in the silicon substrate 1 so as to sandwich the gate electrode 4. The sidewall spacer 8 shown in FIG. 1 has a two-layer structure in which a silicon nitride film 7 is formed on a silicon oxide film 6.

According to the semiconductor device in this embodiment, as shown in FIG. 1, a protection film 20 is further formed on the end surface of the silicon oxide film 6 positioned at the lowermost layer of the sidewall spacer 8 (on the side of the source region and drain region). This protection film 20 covers the end surface of the silicon oxide film 6 on the side of the source region and the drain region without extending to the lower layer of the silicon nitride film 7. The protection film 20 may be a silicon nitride film or a SiOC film that is hardly etched away by a HF solution or may be a silicon oxide film. Although the protection film 20 is etched away by the HF solution when it is the silicon oxide film, when the thickness of the protection film 20 is sufficiently provided so that the silicon oxide film 6 of the sidewall spacer 8 is not etched away, the object of the present invention can be attained.

According to the semiconductor device in this embodiment, since the protection film 20 is provided, even when the cleaning is performed with the HF solution to remove a natural oxide film, the silicon oxide film 6 is not retreated, so that when a metal film 10 shown in FIG. 11 is formed, it is not formed under the sidewall spacer 8 and the protection film 20. Therefore, according to the semiconductor device in this embodiment, even when the metal silicide film 11 is formed from the metal film 10 shown in FIG. 11 by a heat treatment, the metal silicide film 11 does not extend from the end of the sidewall spacer 8 toward the gate electrode 4 (in the direction from the region of the second impurity diffusion layer 9 toward the region of the first impurity diffusion layer 5) and not grow there.

In addition, the protection film 20 is a silicide protection film (silicide formation preventing film). The silicide protection film prevents the MIS transistor in which the metal silicide layer is not formed, from becoming silicide before a metal silicide layer is formed at a desired region. Therefore, the silicide protection film is formed after the gate electrode, the sidewall and the source and drain regions of the MIS transistor have been formed and before the metal silicide layer is formed. In addition, the silicide protection film is a silicon oxide film in general, and needs to have a thickness (50 nm, for example) to prevent the reaction between metal and silicon at a circuit region in which the metal silicide layer is not formed.

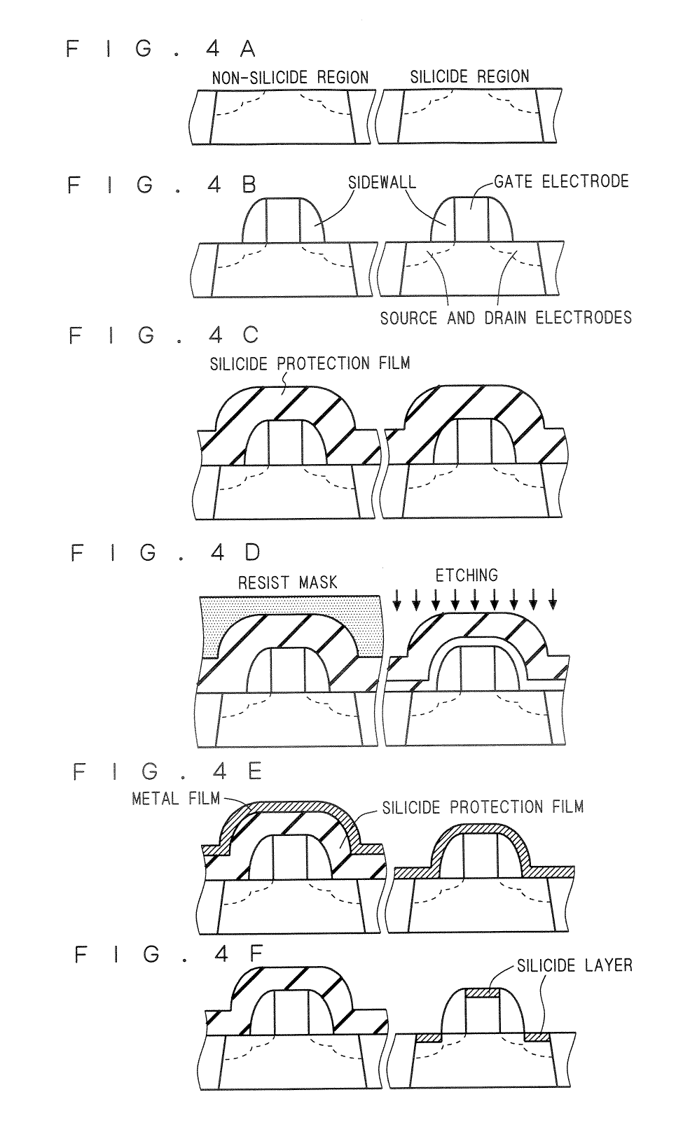

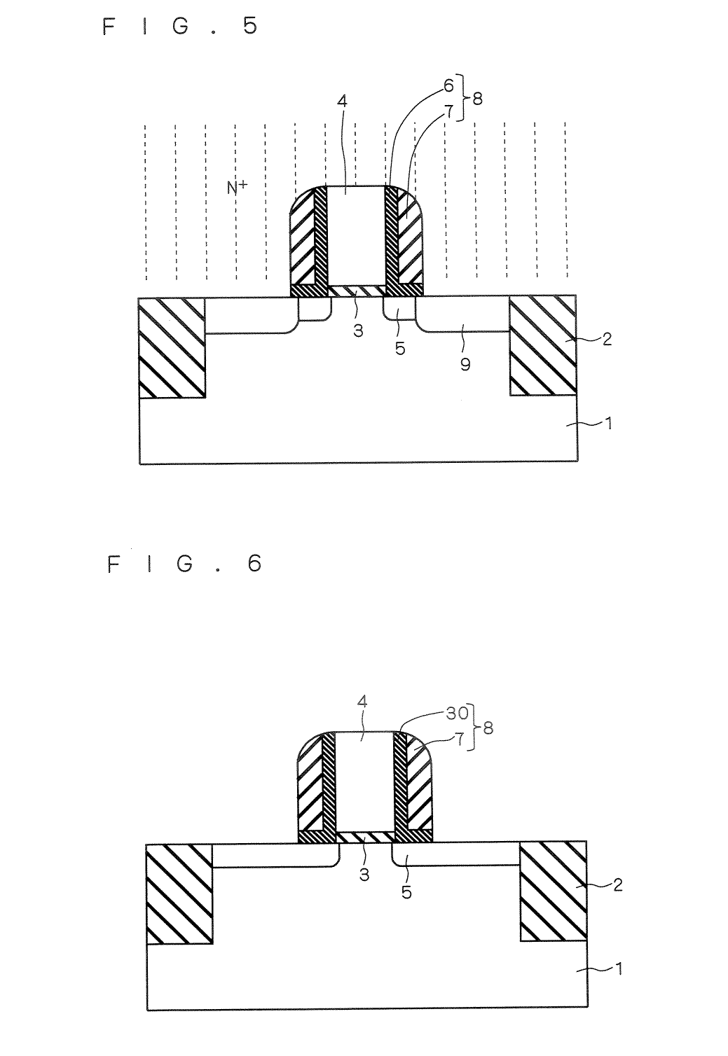

Next, a method of forming the silicide protection film will be described with reference to FIGS. 4A to 4F hereinafter. First, FIG. 4A shows a non-silicide region and a silicide region on the same semiconductor substrate. Then, as shown in FIG. 4B, a gate electrode, a sidewall and source and drain regions are formed in each region. Furthermore, as shown in FIG. 4C, a silicide protection film is formed on the whole surface including both regions.

Then, as shown in FIG. 4D, a resist mask is only formed on the silicide protection film in the non-silicide region and the silicide protection film in the silicide region is etched away. That is, only the silicide region in which a metal silicon layer will be formed in the future is etched away using the resist mask. Then, as shown in FIG. 4E, a metal film to form silicide is formed on the whole surface including both regions. That is, the metal layer is formed on the silicide protection film in the non-silicide region and on the gate electrode, the sidewall and the source and drain regions in the silicide region. Finally, as shown in FIG. 4F, the heat treatment is performed and a nonreacted metal film is removed, whereby the silicide protection film and a silicide layer are formed in the non-silicide region and silicide-region, respectively.

Next, the manufacturing method of the semiconductor device according to this embodiment will be described. First, according to the manufacturing method of the semiconductor device in this embodiment, the steps until the protection film 20 is formed on the end surface of the silicon oxide film 6 are the same as those in the background art. More specifically, steps until the step shown in FIG. 10 are the same. Therefore, the description of the steps until the step shown in FIG. 10 is omitted in this embodiment.

After the step shown in FIG. 10, an insulation film 21 (a silicon oxide film, for example) is formed by CVD and the like and the protection film 20 is formed. The thickness of the insulation film 21 is 5 to 50 nm, for example. FIG. 2 shows a sectional view showing the semiconductor device in which the insulation film 21 is formed. In addition, since the end surface of the silicon oxide film 6 does not exist inside the end surface of the silicon nitride film 7 (on the side of the gate electrode 4) before the insulation film 21 is formed, the insulation film 21 (that will become the protection film 20) does not extend to the lower layer of the silicon nitride film 7.

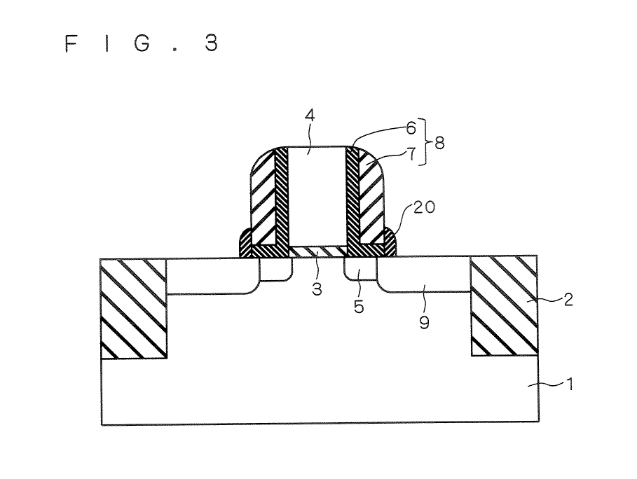

Then, the protection film 20 is formed by etching back the insulation film 21. This protection film 20 protects the end surface of the silicon oxide film 6 positioned at the lowermost layer of the sidewall spacer 8. According to the protection film 20 shown in FIG. 3, although a part of the silicon nitride film 7 is also covered in addition to the end surface of the silicon oxide film 6, the size of the protection film 20 is not limited as long as it does not affect the characteristics of the semiconductor device.

Then, the natural oxide film on the surface of the silicon substrate 1 is removed by cleaning with the HF solution (hydrofluoric acid). The semiconductor device shown in FIG. 1 is formed through steps shown in FIGS. 11 and 12 described in the background art. In addition, as described above, when the protection film 20 is the silicon oxide film, the thickness of the protection film 20 is reduced at the cleaning step by the HF solution (hydrofluoric acid). However, when the thickness of the protection film 20 is formed more thickly than the thickness etched away the HF solution (hydrofluoric acid) cleaning, the silicon oxide film 6 of the sidewall spacer 8 is prevented from being etched away.

In addition, when the material of the protection film 20 is a silicon nitride film or a SiOC film instead of the silicon oxide film, the etching resistance against the HF solution (hydrofluoric acid) is improved. Thus, the silicon oxide film 6 of the sidewall spacer 8 can be further prevented from being etched away.

In addition, instead of the cleaning with the HF solution (hydrofluoric acid), the natural oxide film on the surface may be removed by a plasma treatment with gas containing fluorine such as NF₃. In this case also, when the protection film 20 is formed like in this embodiment, the silicon oxide film 6 of the sidewall spacer 8 can be more effectively prevented from being etched away.

As described above, according to the semiconductor device in this embodiment, since the protection film 20 that covers the end surface of the silicon oxide film 6 on the side of the source region and the drain region is provided without extending to the lower layer of the silicon nitride film 7, the silicon oxide film 6 of the sidewall spacer 8 is prevented from being etched away by the HF solution (hydrofluoric acid) cleaning, so that the metal silicide film 11 is prevented from entering the first impurity diffusion layer, and the unnecessary junction leak current is prevented from being increased.

In addition, although the metal silicide film 11 is not particularly limited in this embodiment, in a case where the metal silicide film 11 comprises NiSi, the effect to prevent the increase in junction leak current is greater than a case where it comprises CoSi₂. Because, in the case where the metal silicide film 11 comprises NiSi, since the metal silicide film 11 grows in the surface direction of the silicon substrate 1 more than the case where it comprises CoSi₂, the junction leak current of a gate edge component generated at a gate edge part is increased. Thus, according to the semiconductor device in this embodiment, since the metal silicide film 11 is prevented from entering the first impurity diffusion layer (in the direction of the gate electrode 4), the junction leak current of the gate edge component can be effectively prevented in the case NiSi is used for the metal silicide film 11. In addition, according to a recent transistor having a LDD (Lightly Doped Drain) structure, the lower part of a sidewall spacer 8 is different in profile and junction structure.

In addition, according to the semiconductor device in this embodiment, since the HF solution (hydrofluoric acid) cleaning is performed to remove the natural oxide film on the surface of the silicon substrate 1 after the protection film 20 has been formed. In this case, since a wet processing device to perform the HF solution (hydrofluoric acid) cleaning and a sputtering device to form the metal film 10 (Ni, for example) thereafter are different, a standby time (storage) is generated between both steps. Since this standby time affects the characteristics of the semiconductor device, it is necessary to control the standby time according to the above manufacturing method.

However, the present invention is not limited to the above manufacturing method and the semiconductor device may be manufactured by a method in which the natural oxide film on the surface of the silicon substrate 1 is removed by an in-situ process (process without exposure to air). More specifically, according to that manufacturing method, after the protection film 20 has been formed, the natural oxide film is removed by chemical dry cleaning in the same clustered device and then the metal film 10 (Ni, for example) is formed by sputtering. According to this method, since the chemical dry cleaning and the sputtering are performed as an in-situ process, it does not need to control the standby time.

### Embodiment 2

According to the semiconductor device in the embodiment 1, the protection film 20 is provided on the end surface of the silicon oxide film 6 positioned at the lowermost layer of the sidewall spacer 8 to prevent the silicon oxide film 6 from being etched away by the HF solution (hydrofluoric acid). However, according to a semiconductor device in this embodiment, a process to improve the etching resistance of the silicon oxide film 6 itself against the HF solution (hydrofluoric acid) without providing the protection film 20.

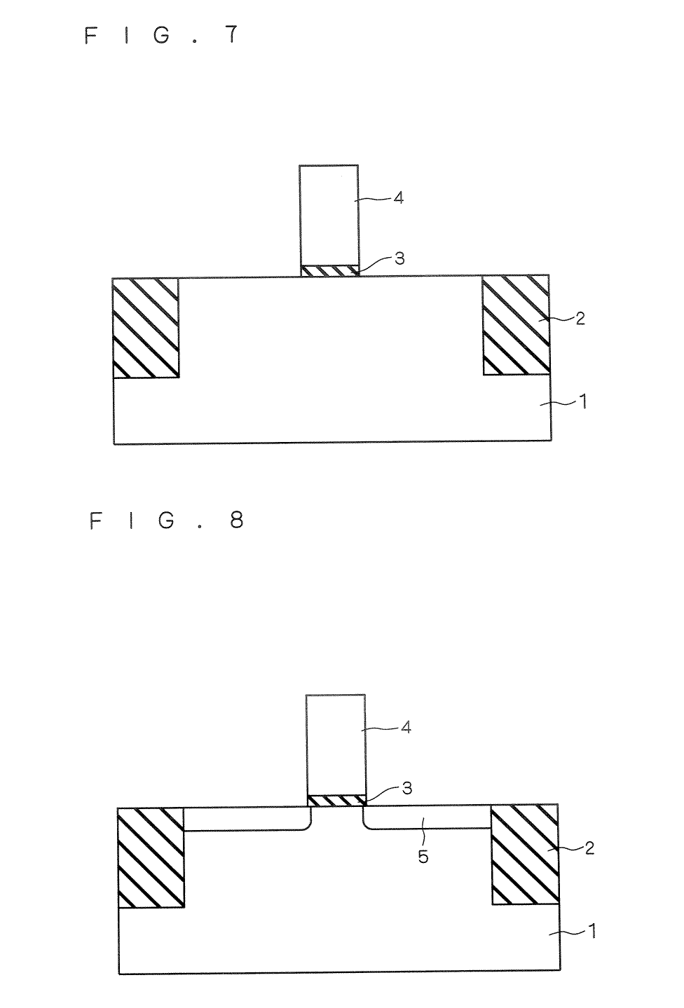

According to the semiconductor device in this embodiment, in order to improve the etching resistance of the silicon oxide film 6, a plasma treatment is performed in a nitrogen atmosphere after the step shown in FIG. 10. The temperature of the plasma treatment is set at a temperature (room temperature to 400° C.) lower than the formation temperature of the protection film 20 (400 to 500° C., for example). FIG. 5 is a conceptual view showing that the semiconductor device is plasma treated in the nitrogen atmosphere after the step shown in FIG. 10. Dotted lines in FIG. 5 designate the nitrogen atmosphere conceptually.

As shown in FIG. 5, when the plasma treatment is performed in the nitrogen atmosphere, the end surface of the silicon oxide film 6 positioned at the lowermost layer in the sidewall spacer 8 (on the side of the source region and the drain region) is nitrided and becomes a SiON film. When the end surface of the silicon oxide film 6 becomes the SiON film, the etching resistance against the subsequent HF solution (hydrofluoric acid) cleaning is improved. When the etching resistance of the silicon oxide film 6 is improved, the silicon oxide film 6 is prevented from being retreated and an unnecessary junction leak current is prevented from being increased.

As described above, since the end surface of the silicon oxide film 6 positioned at the lowermost layer in the sidewall spacer 8 is nitrided by the plasma treatment in the nitrogen atmosphere, in the semiconductor device according to this embodiment, the silicon oxide film 6 is prevented from being etched away by the HF solution (hydrofluoric acid), and the unnecessary junction leak current is prevented from being increased. Furthermore, according to the semiconductor device in this embodiment, although the protection effect for the silicon oxide film 6 is inferior to that of the embodiment 1, since the step of providing the protection film 20 is omitted, the process steps can be simplified.

### Embodiment 3

According to the semiconductor device in the embodiment 2, the end surface of the silicon oxide film 6 is nitrided by performing the plasma treatment in the nitrogen atmosphere. Meanwhile, according to a semiconductor device in this embodiment, the end surface of a silicon oxide film 6 is carbonized by performing a plasma treatment in a gas atmosphere containing carbon instead of the nitrogen atmosphere. In addition, the gas containing carbon includes CF₄, CH₄, CHF₃, CN and CO₂.

According to the semiconductor device in this embodiment, in order to improve the etching resistance of the silicon oxide film 6, the plasma treatment is performed in the atmosphere of gas containing carbon after the step shown in FIG. 10. The temperature of the plasma treatment is set at a temperature (room temperature to 400° C.) lower than the formation temperature of the protection film 20 (400 to 500° C., for example).

When the plasma treatment is performed in the gas atmosphere containing carbon, the end surface of the silicon oxide film 6 positioned at the lowermost layer in the sidewall spacer 8 (on the side of the source region and the drain region) is carbonized and becomes a SiOC film. When the end surface of the silicon oxide film 6 becomes the SiOC film, the etching resistance against the subsequent HF solution (hydrofluoric acid) is improved. When the etching resistance of the silicon oxide film 6 is improved, the silicon oxide film 6 is prevented from being retreated and an unnecessary junction leak current is prevented from being increased.

As described above, since the end surface of the silicon oxide film 6 positioned at the lowermost layer in the sidewall spacer 8 is carbonized by the plasma treatment in the gas atmosphere containing carbon, in the semiconductor device according to this embodiment, the silicon oxide film 6 is prevented from being etched away by the HF solution (hydrofluoric acid), and the unnecessary junction leak current is prevented from being increased. Furthermore, according to the semiconductor device in this embodiment, although the protection effect for the silicon oxide film 6 is inferior to that of the embodiment 1, since the step of providing the protection film 20 is omitted, the process steps can be simplified.

### Embodiment 4

According to the semiconductor device in the embodiments 1 to 3, the lowermost layer of the sidewall spacer 8 is the silicon oxide film 6. Therefore, the silicon oxide film 6 is etched away by the HF solution (hydrofluoric acid) cleaning. Thus, according to a semiconductor device in this embodiment, an SiOC film superior in etching resistance against hydrofluoric acid is used instead of the silicon oxide film 6.

At the step shown in FIG. 9 described in the background art, a SiOC film (silicon carbonation film) 30 is formed by CVD as shown in FIG. 6 instead of forming the silicon oxide film 6. The SiOC film 30 may be formed by the already practically used well-known CVD method as an interlayer insulation film. A silicon nitride film 7 is formed on the SiOC film 30 and the SiOC film 30 and the silicon nitride film 7 are treated by etching back, to form a sidewall spacer 8 that covers the side surfaces of the gate insulation film 3 and the gate electrode 4. As shown in FIG. 6, according to the sidewall spacer 8, the silicon nitride film 7 is laminated on the lower SiOC film 30. In addition, although the sidewall spacer 8 has a two-layer structure in FIG. 6, it may have a multilayer structure comprising three or more layers in which the lowermost layer is the SiOC film 30.

Since the SiOC film 30 is superior in etching resistance against hydrofluoric acid (HF), the lowermost SiOC film 30 of the sidewall spacer 8 can be prevented from being retreated at the step of HF solution (hydrofluoric acid) performed before the metal film 10 is formed. Thus, a metal silicide film 11 is prevented from entering a first impurity diffusion layer region and an unnecessary junction leak current is prevented from being increased. Since the SiOC film 30 is used instead of the silicon oxide film 6, it is not necessary to form the protection film 20 and the steps can be more simplified.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate;
a gate electrode formed on a main surface of said semiconductor substrate with a gate insulation film therethrough;
a sidewall spacer formed so as to cover a side surface of said gate electrode and including at least two layers of a silicon oxide film as a lowermost layer and a silicon nitride film formed thereon;
a source region and a drain region formed in the main surface of said semiconductor substrate so as to sandwich said gate electrode;
a protection film formed so as to cover an end surface of said silicon oxide film without extending below said silicon nitride film, the end surface being on a side of said source region and said drain region; and
a metal silicide layer formed in said source region and said drain region on a side of said protection film away from said gate electrode.

2. The semiconductor device according to claim 1, wherein said protection film is a silicon oxide film.

3. The semiconductor device according to claim 1, wherein said protection film is a silicon nitride film.

4. The semiconductor device according to claim 1, wherein said protection film is an SiOC film.

5. A semiconductor device comprising:
a semiconductor substrate;
a gate electrode formed on a main surface of said semiconductor substrate with a gate insulation film therethrough;
a sidewall spacer formed so as to cover a side surface of said gate electrode and including at least two layers of a silicon oxide film as a lowermost layer and a silicon nitride film formed thereon;
a source region and a drain region formed in the main surface of said semiconductor substrate so as to sandwich said gate electrode; and
a metal silicide layer formed in said source region and said drain region on a side of said sidewall spacer away from said gate electrode, wherein
said silicon oxide film is nitrided at an end surface on the side of said source region and said drain region.

6. A semiconductor device comprising:
a semiconductor substrate;
a gate electrode formed on a main surface of said semiconductor substrate with a gate insulation film therethrough;
a sidewall spacer formed so as to cover a side surface of said gate electrode and including at least two layers of a silicon oxide film as a lowermost layer and a silicon nitride film formed thereon;
a source region and a drain region formed in the main surface of said semiconductor substrate so as to sandwich said gate electrode; and
a metal silicide layer formed in said source region and said drain region on a side of said sidewall spacer away from said gate electrode, wherein
said silicon oxide film is carbonized at an end surface on the side of said source region and said drain region.

7. A semiconductor device comprising:
a semiconductor substrate;
a gate electrode formed on a main surface of said semiconductor substrate with a gate insulation film therethrough;
a sidewall spacer formed so as to cover a side surface of said gate electrode and including a plurality of layers that include an SiOC film as a lowermost layer;
a source region and a drain region formed in the main surface of said semiconductor substrate so as to sandwich said gate electrode; and
a metal silicide layer formed in said source region and said drain region on a side of said sidewall spacer away from said gate electrode.

8. A manufacturing method of a semiconductor device comprising the steps of:
forming a gate electrode on a main surface of said semiconductor substrate with a gate insulation film therethrough;
forming a source region and a drain region in the main surface of said semiconductor substrate so as to sandwich said gate electrode;
forming a sidewall spacer that covers a side surface of said gate electrode and includes at least two layers of a silicon oxide film as a lowermost layer and a silicon nitride film formed thereon;
forming a protection film formed so as to cover at least an end surface of said silicon oxide film on a side of said source region and said drain region by forming an insulation film and etching back said insulation film after said sidewall spacer has been formed; and
forming a metal silicide layer in said source region and said drain region on a side of said sidewall spacer away from said gate electrode.

9. A manufacturing method of a semiconductor device comprising the steps of:
forming a gate electrode on a main surface of said semiconductor substrate with a gate insulation film therethrough;
forming a source region and a drain region in the main surface of said semiconductor substrate so as to sandwich said gate electrode;
forming a sidewall spacer that covers a side surface of said gate electrode and includes at least two layers of a silicon oxide film as a lowermost layer and a silicon nitride film formed thereon;
nitriding at least an end surface of said silicon oxide film on a side of said source region and said drain region by performing a plasma treatment in an atmosphere containing nitrogen after said sidewall spacer has been formed; and
forming a metal silicide layer in said source region and said drain region on a side of said sidewall spacer away from said gate electrode.

10. A manufacturing method of a semiconductor device comprising the steps of:
forming a gate electrode on a main surface of said semiconductor substrate with a gate insulation film therethrough;
forming a source region and a drain region in the main surface of said semiconductor substrate so as to sandwich said gate electrode;
forming a sidewall spacer that covers a side surface of said gate electrode and includes at least two layers of a silicon oxide film as a lowermost layer and a silicon nitride film formed thereon;
carbonizing at least an end surface of said silicon oxide film on a side of said source region and said drain region by performing a plasma treatment in a gas atmosphere containing carbon after said sidewall spacer has been formed; and
forming a metal silicide layer in said source region and said drain region on a side of said sidewall spacer away from said gate electrode.
